(19) United States
(12) Patent Application Publication
(10) Pub. No.: US 2026/0122779 A1
(43) Pub. Date: Apr. 30, 2026

(54) MULTILAYER STRETCHABLE PRINTED CIRCUIT BOARD

(71) Applicant: Worcester Polytechnic Institute, Worcester, MA (US)

(72) Inventors: Pratap Rao, Northborough, MA (US); Ritwik Pandey, Worcester, MA (US); Nicholas R. Pratt, Worcester, MA (US); Markus P. Nemitz, Southborough, MA (US)

(21) Appl. No.: 19/004,777

(22) Filed: Dec. 30, 2024

Related U.S. Application Data
(60) Provisional application No. 63/616,947, filed on Jan. 2, 2024.

(51) Int. Cl. H05K 1/02; H05K 1/11; H05K 1/18; H05K 3/28; H05K 3/30

(52) U.S. Cl. CPC H05K 1/0283; H05K 1/115; H05K 1/181; H05K 3/284; H05K 3/303; H05K 2201/09272; H05K 2201/09381; H05K 2201/09609; H05K 2201/10037; H05K 2201/10106

(57) ABSTRACT

A flexible trace formed from a fluidic, conductive material deposited onto a flexible and stretchable substrate forms a stretchable and deformable circuit for implementations subject to bending and flexing such as soft robotics and textile application such as clothing. An encapsulation layer forms a convex vessel over the flexible trace, and additional circuit layers are accommodated on the encapsulation layer by forming an aperture in the encapsulation layer for defining a via, and depositing a trace on the encapsulation layer engaged with the aperture. Successive encapsulation layers may serve as successive substrate layers for additional traces deposition or printing, followed by a final encapsulation layer for fully enclosing the traces and any placed components. As the layers are deformable and stretchable, and the traces are a fluidic, conductive material, the entire structure is flexible and deformable without compromising the electrical continuity of the deposited traces and connected components.

### RELATED APPLICATIONS

This patent application claims the benefit under 35 U.S.C. § 119 (e) of U.S. Provisional Patent App. No. 63/616,947, filed Jan. 2, 2024, entitled “MULTILAYER STRETCHABLE PRINTED CIRCUIT BOARD,” incorporated herein by reference in entirety.

### BACKGROUND

Traditional PCB materials and manufacturing methods can make only rigid and flexible boards, and typically employ a subtractive processes that can result in substantial waste and use of hazardous chemicals. More recently, print and deposition approaches have evolved to forming traces in an additive method, marking improvements in waste and volatile chemicals in conventional PCB manufacturing.

### SUMMARY

Soft and stretchable boards that are easily manufacturable are preferable for applications such as wearable devices and soft robotic applications. An easily manufacturable additive method that uses widely-available equipment and commercially-available materials to make soft stretchable multilayer circuits is proposed. A flexible trace formed from a fluidic, conductive material deposited onto a stretchable, flexible and deformable substrate forms a deformable circuit for implementations subject to bending and flexing such as soft robotics and textile applications including clothing and worn devices. An encapsulation layer forms a convex vessel over the flexible trace, and additional circuit layers are accommodated on the encapsulation layer by forming an aperture in the encapsulation layer for defining a via, and depositing a trace on the encapsulation layer engaged with the aperture. Successive encapsulation layers may serve as successive substrate layers for additional traces deposition or printing, followed by a final encapsulation layer for fully enclosing the traces and any placed components. As the layers are deformable and stretchable, and the traces are a fluidic, conductive material, the entire structure is flexible and deformable without compromising the electrical continuity of the deposited traces and connected components.

The result is a highly manufacturable method of fabricating stretchable multi-layer printed circuitry that allows electronic components to be embedded within the flexible circuit. Commercially available solutions may allow some flexibility, but are not stretchable, making them unsuitable for applications in soft robotics and wearables. Configurations herein provide an alternative that is highly stretchable (to well over 200%), extremely manufacturable (fully automatable), and easily customisable through a fully digital process.

Configurations herein are based, in part, on the observation that electronic circuits are deployable in a variety of locations, given the combination of low-power draw LED components and small, powerful batteries available with modern technology. Unfortunately, conventional approaches to electronic circuits suffer from the shortcoming of rigid printed circuit board (PCB) material with solid metal traces that can be compromised by bending forces or vibrations. Accordingly, configurations herein substantially overcome the shortcomings of conventional rigid circuits by providing a flexible, multilayer circuit board applicable to contexts such as textiles or worn materials and soft bodied robots, such that the circuit maintains electrical connectivity through stretching, bending and other deformations.

Conventional circuits rely on rigid, printed circuit boards (PCBs) that employ conductive strips and solder holes for circuit elements. Configurations herein present a stretchable substrate employed for receiving circuit traces that are also flexible and stretchable. The stretchable substrate disclosed herein extends beyond flexible and deformable material used for circuit construction. A flexible material, such as a planar sheet, can bend or flex out of an x-y plane defining the longest dimensions. A stretchable material, as disclosed herein, has the ability to extend in plane along the x-y dimensions, effectively forming a larger planar area, in addition to deforming out of plane, without disrupting the continuity of the flexible traces deposited and adhered thereto.

In further detail, configurations herein show formation of a flexible circuit by depositing or printing conductive traces on a deformable substrate and layering a nonconductive encapsulation layer on the deformable substrate for encapsulating the conductive traces. The nonconductive layer is adhered to the deformable substrate for forming enclosed regions around the conductive traces, where all of the deformable substrate, nonconductive layer and conductive traces configured to deform while maintaining electrical continuity along the conductive traces. Additional layers may be iteratively added.

### BRIEF DESCRIPTION OF THE DRAWINGS

The foregoing and other features will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles of the invention.

FIG. 1 is a perspective view of the multi-layer, stretchable circuit;

FIG. 2 is a schematic side view of a layered circuit as in FIG. 1;

FIG. 3 is an exploded view of the circuit of FIG. 1;

FIGS. 4A-4D show an assembly of external contacts and components in the circuit of FIGS. 1-3; and

FIGS. 5A-5B show views of a printed or deposited traces formed in the circuit of FIGS. 1-4D; and

FIG. 6 show results of experiments of cycling deformation in the circuits of FIGS. 1-5B.

### DETAILED DESCRIPTION

Configurations herein provide a method for forming a multi-layer circuit by forming conductive traces on a deformable substrate, and placing electronic components in electrical communication with the traces. Encapsulation of the traces and electronic components with a non-conductive layer allows for forming a second and successive layers including vias for connecting to additional conductive traces printed on the non-conductive layer.

Configurations disclosed below present a fully digital method for the additive manufacturing of highly stretchable multilayer circuits. The conductive circuits and vias are composed of a commercially available liquid metal ink, which is printed onto stretchable thermoplastic polyurethane (TPU) sheets by an additive direct ink write (DIW) process that is suitable for digital prototyping and manufacturing. Surface mount components are placed directly onto the liquid metal circuit, and in an absence of any adhesive or solder. An encapsulant layer is then deposited, which encapsulates both the printed liquid metal traces and the placed components, resulting in a robust assembly onto which the next layer can be fabricated. Circuit trace printing, component placement and encapsulation are then repeated to build up multiple layers, each layer with its own stretchable circuit and placed components. Interlayer vias are fabricated by creating holes in the encapsulant layers, which are filled by liquid metal printed in the next circuit layer.

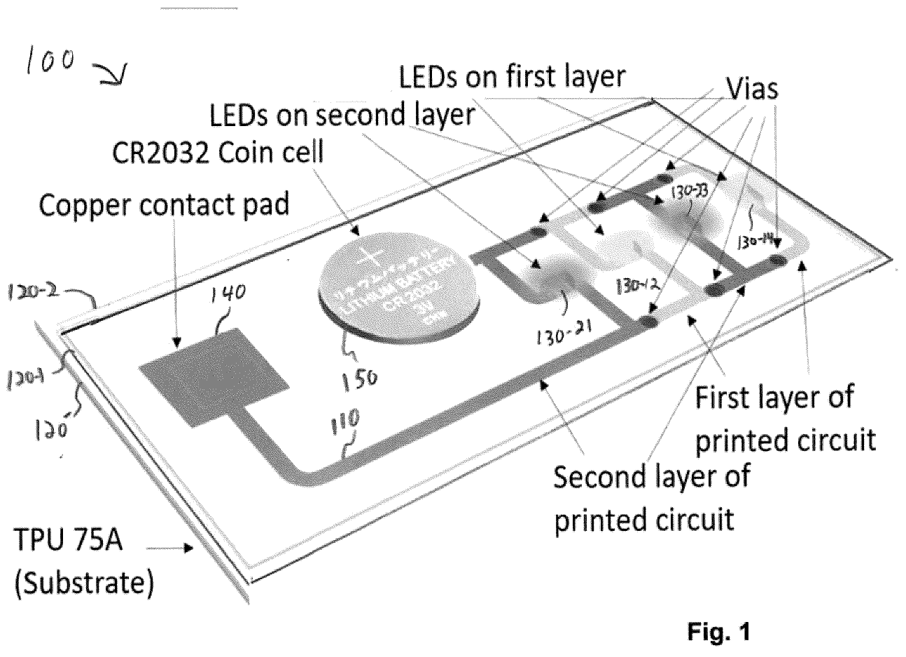

FIG. 1 is a perspective view of the multi-layer, stretchable circuit 100. In a general configuration in FIG. 1, the circuit includes traces 110 embedded between layers 120-1 . . . 120-2 layered on a substrate 120′ (120 generally), which may all be formed from the same material such as a sheet of thermoplastic or similar non-conductive material. Components 130-12 . . . 130-23 (130 generally) such as LEDs reside on the layers (including the substrate layer 120′), along with contact pads 140 and a power supply 150 such as a coin cell.

Traces 110 and pads of a conductive deformable liquid/paste/gel (liquid metal being the preferred embodiment) are fabricated on the substrate 120′ by means of direct ink write (DIW) printing or any other printing or deposition and patterning process on a thermoplastic polyurethane or other equivalent stretchable substrate 120′. Electronic components 130 are aligned and placed on the pads defined by the traces. An encapsulant layer 120 of thermoplastic polyurethane (TPU), or additive curing elastomer is laminated (hot pressed or adhesive), printed, coated or cast on. Embedding of the components 130 on internal layers allow multi-layer circuit structures to be formed. Gaps left in the encapsulant over sections of the traces 110 below form interconnects, or vias, to the circuit printed (or otherwise deposited) on the encapsulant layer 120 above. In an example configuration, interlayer adhesion may be performed by hot pressed lamination of a laser cut TPU sheet with holes for vias. The substrate 120′ and subsequent layers 120 are selected for subsequent fusion and adherence, such as through heat bonding, fusion, adhesive or similar attachment between opposed planar layers 120.

Conventional approaches to non-rigid implementations employ techniques such as flexible electroplated and photolithographically patterned sheets, or perform filling of liquid metal into pre-cut features/channels in a sheet followed by lamination and filling of other pre-cut sheets to build up a multilayer stack. In contrast, the claimed approach deposits a fluid, conductive medium onto a flat, planar surface for forming the conductive traces 110, which hold their deposited form in with a semisolid, suspension or gel-like property until the encapsulating layer 120 is fused or adhered onto the substrate 120′.

In one example configuration, 1608 and 1005 size components were placed directly onto the liquid metal circuits with no additional adhesive or solder, and were encapsulated by the layer 120 defined by a laminated TPU sheet to form a robust assembly. The stretchable circuits were consistently able to withstand hundreds of cycles of 225% strain (the maximum tested) with less than 1.2002 drift in resistance for 5 cm long test specimens. Circuits with vias and placed components had similar cyclic stretching performance with only modest additional resistances. A final 2-layer circuit consisting of LEDs in both layers was fabricated as a stretchable demonstrator device. While the demonstrated digital DIW process is suitable for prototyping stretchable circuits, the overall process is also compatible with other printing methods including screen printing, which can be used for higher throughput production.

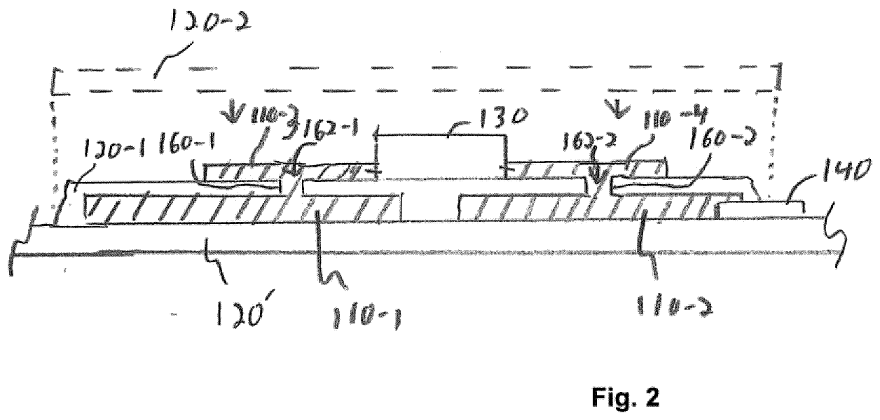

FIG. 2 is a schematic side view of a layered circuit as in FIG. 1 showing the vertical orientation of the layers 120. The bottommost layer 120′ forms the substrate first layer. Traces 110-1 and 110-2 are printed on top of the substrate 120′, and trace 110-2 contacts a contact pad 140 for external solder, clamp or spring-biased external connections. Layer 120-1 has apertures 162-1 and 162-2 for forming vias 160-1 and 160-2, which form upon deposition of traces 110-3 and 110-4 to fill the apertures flanking component 130. Layer 120-1 encapsulates substrate 120′, effectively forming vessels over the traces 110-1 and 110-2. Layer 120-2, upon adherence, encapsulates traces 110-3 and 110-4 along with component 130, selected to have a height within the deformability of the layer 120-2 for molding over the component 130 and connected traces 110.

The example configuration employs direct ink write (DIW) as the printing or deposition medium. Other suitable approaches form the conductive traces 110 based on material deposition from at least one of direct ink write, fused deposition, aerosol jet printing, screen printing and stencil printing, and deposit a pattern of the conductive traces having conductive unions based on a predetermined circuit plan.

Successive layers may therefore be formed by forming gaps from apertures 162 in the non-conductive layer 120, and placing additional electronic components 130 in alignment with the gaps and/or in electrical communication with the traces 110 on the deformable substrate 120′, thus allowing the traces 110 to contact traces on lower levels.

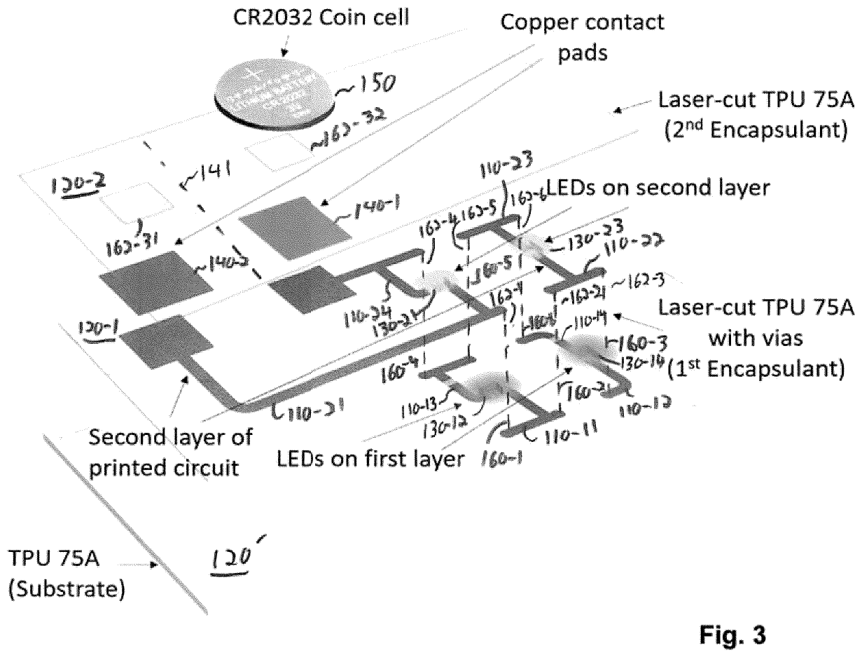

FIG. 3 is an exploded view of the circuit of FIG. 1, or, more precisely, illustrating layer formation as successive layers 120 are applied and adhered. Proceeding in a sequential process, the method for forming the flexible circuit 100 includes forming conductive traces 110 on a deformable substrate 120′, and placing a component 130 in electrical communication with the conductive traces 110. Vias 160-1 . . . 160-6 may be defined by forming an aperture 162 in a nonconductive layer 120-1, and iterating for each via 160 with a corresponding cutout or aperture 162. A robotic, automated or manual placement then applies the nonconductive layer 120 over the deformable substrate 120,′ including the component 130 and aligning the apertures 162-1 . . . 162-6 (162 generally) with the corresponding conductive traces 110 to encapsulate and seal the traces 110 in a vessel formed between the layers 120′ . . . 120-1 with heat fusing, adhesive or other bonding. A second 120-2 and successive circuit layers may then be formed by depositing additional conductive traces 110 on the nonconductive layer 120-N in electrical communication with the apertures 162 to form the vias 160.

Each successive layer 120-N adheres to lower layers 120-(N−1) down to the deformable substrate 120′ for forming enclosed regions around the conductive traces 120. All of the deformable substrate 120′, nonconductive layers 120-N and conductive traces 110 are configured to deform while maintaining electrical continuity along the conductive traces 110. Typical circuits 100 will also engage at least one external connection from a contact pad 140 in electrical communication to the conductive traces 110. In the example of FIG. 3, a pair of contact pads 140-1 . . . 140-2 allow the outermost pad 140-2 to contact the battery for forming a complete power circuit, by deforming (folding) at dotted line 141.

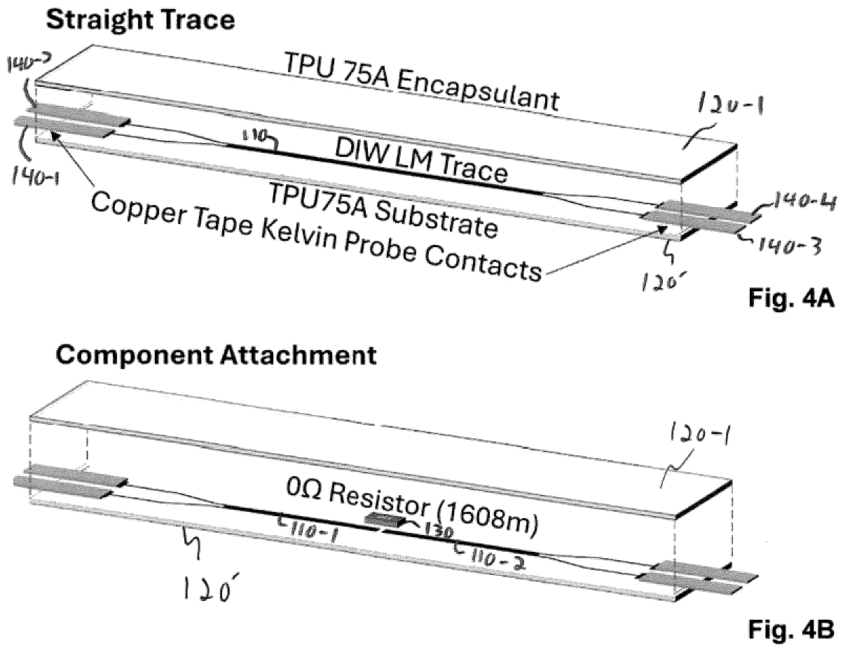

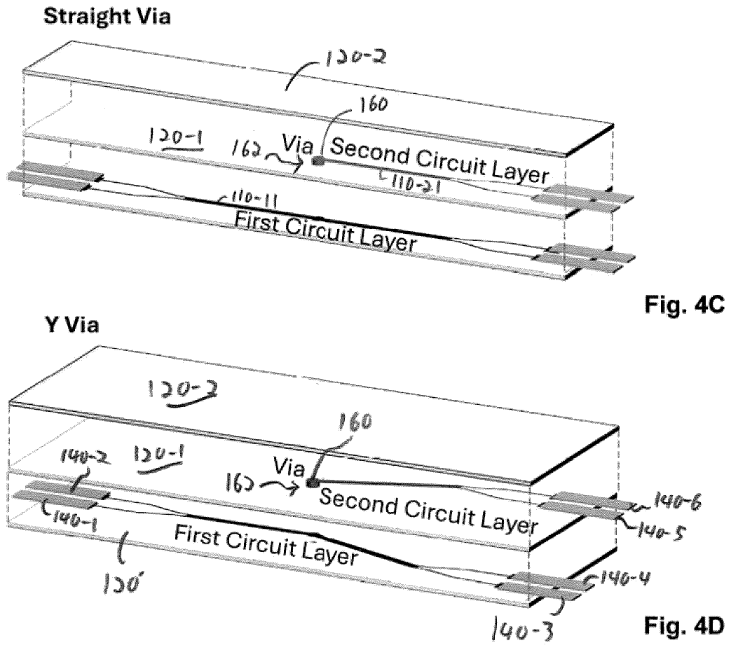

FIGS. 4A-4D show assembly of external contacts and components in the circuit of FIGS. 1-3. External contacts include solid contact pads 140, typically cut from thin sheets of copper. External contacts may also be provided by traces 110 deposited to align with contact points or pins on a component 130, such as an IC, gate, LED, storage (capacitor, inductor) element or passive element. Components 130 may be sufficiently thin (low height/z-axis extent) to be encapsulated under a layer, or apertures 162 may be formed to allow the component 130 to extend above the layer 120.

Referring to FIGS. 4A-4D, specific circuit constructs analogous to conventional PCB circuits are shown. Each of the constructs of FIGS. 4A-4D may, and likely are, combined in any suitable quantity on a production circuit according to configurations herein. In FIG. 4A, a straight trace 110 is shown with two contact pads at each end 140-1 . . . 140-4, with a single encapsulation layer 120-1. FIG. 4B shows a resistive element 130 connected between two traces 110-1 . . . 110-2. The traces 110-1 . . . 110-2 may define contact pads across layers by forming a plurality of apertures 162 in the nonconductive layer based on an arrangement of contact pads on a component 130, and aligning each of the plurality of apertures 162 with respective conductive traces 110. A placement apparatus places the component 130 on the nonconductive layer in alignment with the apertures for establishing electrical communication between the contact pads and the respective conductive traces. Alternatively, if the component 130 is sufficiently small, no apertures are needed and the contact pads are defined by terminal ends of the traces 110 to correspond to the component 130.

FIG. 4C shows a via 160 formed from an aperture 162 between a trace 110-11 on a first layer 120′ to a trace 120-21 on a second layer 120-1, and encapsulated with a top layer 120-2. FIG. 4D shows a Y-via where the via 160 connects with a second layer trace 120-1 and to contact pads 140-5, 140-6 offset from the first (substrate) layer 120′ contact pads 140-3, 140-4. In each case, both the substrate 120′ and the nonconductive layers 120-1, 120-2 are thermoplastic and responsive to heat fusion for bonding to form the encapsulation.

In the implementation of FIGS. 4A-4D, the test traces and circuits may be printed on extruded films of TPU (ESTANER FS L75A4, Lubrizol) having a shore hardness of 75A and a thickness of 4 mils (˜100 μm). The TPU film has polyethylene terephthalate (PET) sheets on both sides, which offer protection from contaminants and scratches, and enable handling of the thin, stretchy TPU film. The PET sheet on one side of the TPU film is peeled off prior to printing. It can be well observed that the deformable substrate initially defines a plane, such that the deformable substrate 120′, nonconductive layers 120-N and conductive traces configured to deform up to about 200% along the plane.

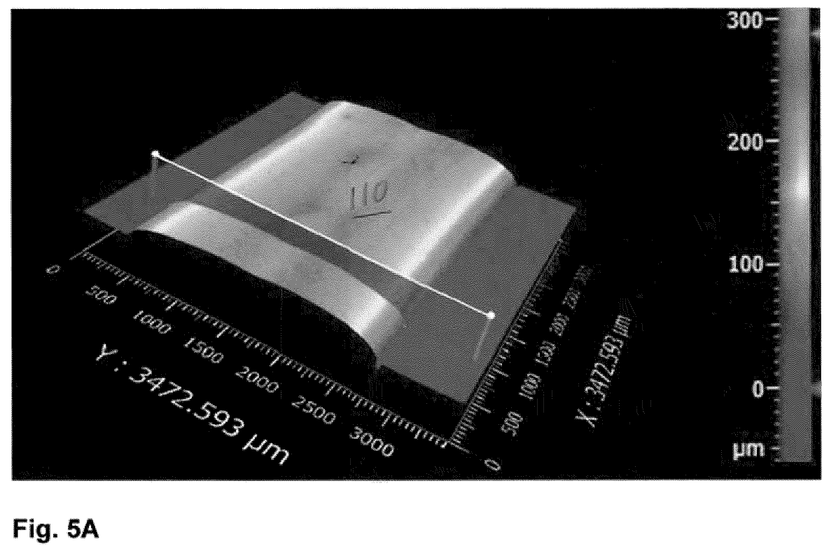

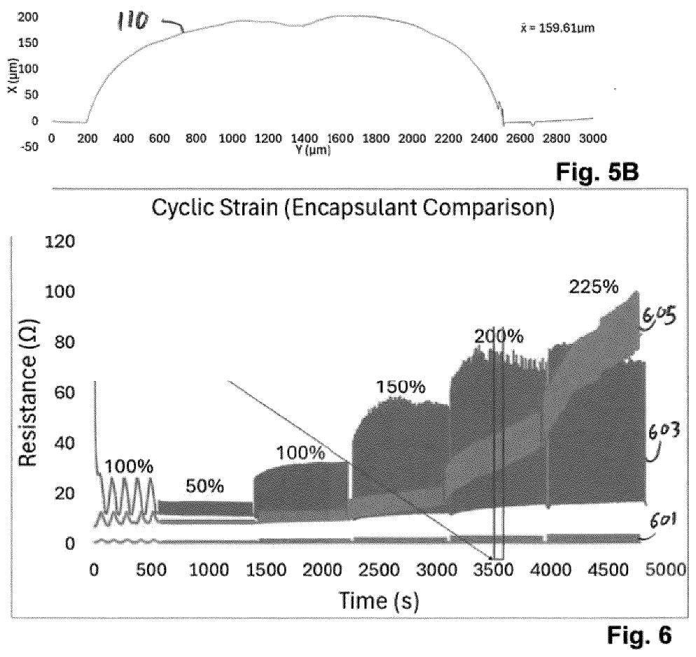

FIGS. 5A-5B show views of printed or deposited traces 110 formed in the circuit of FIGS. 1-4D. The traces 110 form from depositing a conductive fluid material in a gel or viscous form, such as a liquid a gallium alloy. In an example approach, the liquid form results from a fluid composition including capsules containing the conductive gallium alloy. Once deposited, the traces including the capsules are agitated after adhering the nonconductive layer for rupturing the capsules and releasing the conductive material, which fills the vessel formed from the encapsulation.

A commercially available room-temperature liquid metal ink (ELMNT™ ST, UES, Inc.) based on eutectic gallium-indium (cGaIn) alloy was used as an example of the stretchable conductor for the traces 110. The ink has a total metal (gallium-indium) content of 88% by weight, and a viscosity of ˜3000 cP (at a strain rate of 200/s), making it ideal for DIW printing, stencil printing, or screen printing. ELMNT™ is a paste containing nanospheres of liquid gallium-indium alloy, with each nanosphere being stabilized by an oxide shell. The surfaces of the nanospheres are functionalized with organic ligands that cross-link to ligands on adjacent nanospheres to form networks. The printed ink is “activated” by applying a tensile strain large enough to rupture the oxide shells and release the eutectic liquid metal alloy to form a highly stretchable conductive trace.

The ELMNT™ ST ink was printed by a NOVA DIW printer (Voltera) fitted with a ruby tip probe and a motor-controlled plunger. The probe mapped the print surface by sampling a grid with a spacing of 5 mm. The ink was dispensed from a 5 ml syringe with a 225 μm inner-diameter conical precision dispense nozzle (Subrex). The ink was maintained at a temperature of 35° C. to ensure a smooth clog-free flow. The nozzle to substrate distance was set to 150 μm, and the pass width was set to 200 μm with a 210 μm center-to-center spacing between passes, which helps form a relatively smooth trace surface. The print speed (feed rate) was set to 600 mm/min. The NOVA uses unitless numbers to set the dispense and relief pressures, which were set to 500 and 400 respectively. The printing toolpaths start with the trace outline, followed by inward concentric paths to fill in the trace area. Any suitable width for traces may be provided; a typical range is 1-2 mm wide (1000-2000 μm) and about 200 μm thick. Other suitable inks or conductive mediums may be employed, however it is preferable that the fluid, conductive medium retains a deposited form until the nonconductive layer is adhered onto the substrate 120′, such as the 3-dimensional form shown in FIGS. 5A-5B.

FIG. 6 shows results of experiments of cycling deformation in the circuits of FIGS. 1-5B. Alternate encapsulation materials include silicone and VHB (Very High Bond) tape. It should be reiterated that the example ink using capsules of conductive gallium alloy invoke an activation routine for crosslinking and rupturing the capsules, such as stretching, bending, or laser agitation. For silicon, fast cure platinum-catalyzed silicone (Ecoflex™ 00-35 FAST, Smooth-on) was cast on the printed liquid metal traces using a mold to give a 1 mm thick, soft silicone encapsulant. For VHB trials, 10 mil (˜250 μm) thick, clear Very High Bond tape (VHB™ F9473PC, 3M) was pressed onto the printed liquid metal traces ensuring that no air bubbles were trapped in between the substrate and the tape.

Referring to FIG. 6, three specimens of hot-pressed TPU-encapsulated liquid metal traces were fabricated. All three were successfully stretch-activated and had an average R_{0_PA} of 0.71Ω (601), which is an order of magnitude smaller than for the silicone 605 and VHB 603 encapsulated specimens. All three TPU based specimens survived the 1,000 cycles of stretch-testing up to and including 225% strain with an average R_{0_F} of 0.87Ω. These specimens showed an average maximum resistance of 3.28Ω at 225% strain, as shown in FIG. 6.

The resulting device defines the flexible circuit 100 including the deformable substrate 120′ and a pattern of conductive traces 110 formed on the deformable substrate. A plurality of nonconductive layers 120 is deposited on the deformable substrate for encapsulating the conductive traces, where each of the nonconductive layers adheres or fuses to the deformable substrate for forming enclosed regions around the conductive traces. The conductive traces form vias 160 through apertures 162 in the nonconductive layers to traces on other layers. The entire assembly of the deformable substrate, nonconductive layer and conductive traces are configured to deform while maintaining electrical continuity along the conductive traces 110 for applications such as clothing and textiles, wearable medical sensing and soft robotics.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method for forming a stretchable multilayer circuit, comprising:
forming conductive traces on a stretchable substrate;
layering a nonconductive layer on the stretchable substrate for encapsulating the conductive traces; and
adhering the nonconductive layer to the stretchable substrate for forming enclosed regions around the conductive traces, the stretchable substrate, nonconductive layer and conductive traces configured to deform while maintaining electrical continuity along the conductive traces.

2. The method of claim 1 further comprising engaging at least one external connection in electrical communication to the conductive traces.

3. The method of claim 1 wherein the stretchable substrate defines a plane, the stretchable substrate, nonconductive layer and conductive traces configured to deform 200% along the plane.

4. The method of claim 1 further comprising depositing a fluid, conductive medium for forming the conductive traces.

5. The method of claim 4 wherein the fluid, conductive medium retains a deposited form until the nonconductive layer is adhered onto the substrate.

6. The method of claim 1 further comprising:
placing a component in electrical communication with the conductive traces; and
applying the nonconductive layer over the component and the conductive traces.

7. The method of claim 1 further comprising:
defining vias by forming an aperture in the nonconductive layer;
aligning the aperture with one of the conductive traces; and
forming a second circuit layer by forming conductive traces on the nonconductive layer in electrical communication with the aperture.

8. The method of claim 1 further comprising
defining contact pads by forming a plurality of apertures in the nonconductive layer, the plurality of apertures based on an arrangement of contact pads on a component;
aligning each of the plurality of apertures with respective conductive traces; and
placing the component on the nonconductive layer in alignment with the apertures for establishing electrical communication between the contact pads and the respective conductive traces.

9. The method of claim 1 wherein the substrate and the nonconductive layer are thermoplastic and responsive to heat fusion for bonding to form the encapsulation.

10. The method of claim 1 wherein the conductive traces are formed from a gallium alloy.

11. The method of claim 1 further comprising:
depositing the conductive traces as a fluid composition including capsules containing conductive material; and
agitating the capsules after adhering the nonconductive layer for rupturing the capsules and releasing the conductive material.

12. The method of claim 1 further comprising:
forming the conductive traces based on material deposition from at least one of direct ink write, fused deposition, screen printing, stencil printing or aerosol jet printing; and
depositing a pattern of the conductive traces having conductive unions based on a predetermined circuit plan.

13. A flexible circuit device, comprising
a stretchable substrate;
a pattern of conductive traces formed on the stretchable substrate;
at least one nonconductive layer deposited on the stretchable substrate for encapsulating the conductive traces, the nonconductive layer adhered to the stretchable substrate for forming enclosed regions around the conductive traces, the stretchable substrate, nonconductive layer and conductive traces configured to deform while maintaining electrical continuity along the conductive traces.

14. The device of claim 13 further comprising a plurality of nonconductive layers, and vias formed from conductive trace material extending though apertures in a nonconductive layer of the plurality of nonconductive layers for establishing electrical continuity between traces on different layers.

15. The device of claim 13 further comprising external contact pads defined by rigid conductive material extending from the encapsulated traces, the contact pads adapted for electrical connection to a conductive member.

16. The device of claim 13 further comprising at least one component, the component in electrical communication with at least one of the conductive traces, the element further encapsulated between at least one of the conductive layers and the substrate.
